(19) United States
(12) Patent Application Publication
(10) Pub. No.: US 2013/0102143 A1
(43) Pub. Date: Apr. 25, 2013

(54) METHOD OF MAKING A NON-VOLATILE MEMORY CELL HAVING A FLOATING GATE

(71) Applicants: Da Zhang, Austin, TX (US); Frank K. Baker, JR., Austin, TX (US)

(72) Inventors: Da Zhang, Austin, TX (US); Frank K. Baker, JR., Austin, TX (US)

(21) Appl. No.: 13/279,807

(22) Filed: Oct. 24, 2011

(51) Int. Cl. H01L 21/28

(52) U.S. Cl. 438/591; 257/E21.209

(57) ABSTRACT

Forming an NVM structure includes forming a floating gate layer; forming a first dielectric layer over the floating gate layer; forming a plurality of nanocrystals over the first dielectric layer; etching the first dielectric layer using the plurality of nanocrystals as a mask to form dielectric structures, wherein the floating gate layer is exposed between adjacent dielectric structures; etching a first depth into the floating gate layer using the plurality of dielectric structures as a mask to form a plurality of patterned structures, wherein the first depth is less than a thickness of the floating gate layer; patterning the floating gate layer to form a floating gate; forming a second dielectric layer over the floating gate, wherein the second dielectric layer is formed over the patterned structures and on the floating gate layer between adjacent patterned structures; and forming a control gate layer over the second dielectric layer.

### BACKGROUND

1. Field

This disclosure relates generally to non-volatile memories, and more specifically, to non-volatile memories that have a floating gate.

2. Related Art

In floating gate non-volatile memories (NVMs), typically the floating gate is programmed and erased through carriers being transferred between the active region and the floating gate. To obtain enough voltage for the transfer to occur, the overlying control gate is at a relatively high voltage. This relatively high voltage requires special processing so as to avoid damage at that voltage. Although the relatively high voltage is well understood and has been compensated for, any reduction in the magnitude in voltage would be beneficial.

Accordingly, there is a need for reducing the relatively high voltage that is generally required for programming and/or erasing.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a cross section of a semiconductor device at a first stage in processing according to an embodiment;

FIG. 2 is a cross section of the semiconductor device at a stage in processing subsequent to that shown in FIG. 1 according to the embodiment;

FIG. 3 is a cross section of the semiconductor device at a stage in processing subsequent to that shown in FIG. 2 according to the embodiment;

FIG. 4 is a cross section of the semiconductor device at a stage in processing subsequent to that shown in FIG. 3 according to the embodiment;

FIG. 5 is a cross section of the semiconductor device at a stage in processing subsequent to that shown in FIG. 4 according to the embodiment;

FIG. 6 is a cross section of the semiconductor device at a stage in processing subsequent to that shown in FIG. 5 according to the embodiment;

FIG. 7 is a cross section of the semiconductor device at a stage in processing subsequent to that shown in FIG. 6 according to the embodiment; and

FIG. 8 is a cross section of the semiconductor device at a stage in processing subsequent to that shown in FIG. 7 according to the embodiment;

### DETAILED DESCRIPTION

A method of making a non-volatile memory having a floating gate includes forming the floating gate using nanocrystals as a hard mask. The nanocrystals are formed to be relatively small and relatively spaced apart. The nanocrystals are used as a mask to form a patterned hard mask of an immediately underlying dielectric layer. The dielectric layer is then used as a hard mask to etch into a conductive layer that will be used for forming floating gates. The result of the etch is a plurality of pillars extending up from a bottom portion of the conductive layer. With the nanocrystals spaced relatively far apart compared to the case in which the nanocrystals themselves are used as storage elements, the pillars aligned to the nanocrystals are sufficiently far apart to allow formation of an overlying dielectric layer being formed such that the space in between the pillars is not filled when the overlying dielectric is deposited. The floating gate layer is etched, using photoresist patterning, into individual floating gates; one for each memory cell. After forming the overlying dielectric layer over the etched floating gate layer, a subsequent second conductive layer is deposited over the overlying dielectric layer which results in portions of second conductive layer being between the pillars of the floating gate. This increases the capacitance between the floating gate and the control gate which in turn reduces the required voltage for programming and/or erasing. This can reduce the thickness of the second dielectric layer with the result of further increasing the capacitance between the control gate and the floating gate which in turn can further reduce the voltage required on the control gate. This is better understood by reference to the drawings and the following description.

The semiconductor substrate described herein can be any semiconductor material or combinations of materials, such as gallium arsenide, silicon germanium, silicon-on-insulator (SOI), silicon, monocrystalline silicon, the like, and combinations of the above.

Shown in FIG. 1 is a semiconductor device 10 having a substrate 12, isolation 14 formed in substrate 12 used to define memory cell regions, a gate dielectric 16 formed on substrate 12, a conductive layer 18 over gate dielectric 16 and isolation 14, and a dielectric layer 20 over conductive layer 18. Isolation 14 may be of oxide. Gate dielectric 16 may be grown oxide that may be about 100 Angstroms in thickness. Conductive layer 18 may be polysilicon that may be about 1200 Angstroms in thickness; and may be doped in situ as it is deposited or it can be implanted and annealed prior to the formation of dielectric layer 20. Dielectric layer 20 may be a deposited oxide that may be about 100 Angstroms in thickness. The memory cell regions between isolation 14 as shown in FIG. 1 may be a about 1500 Angstroms wide.

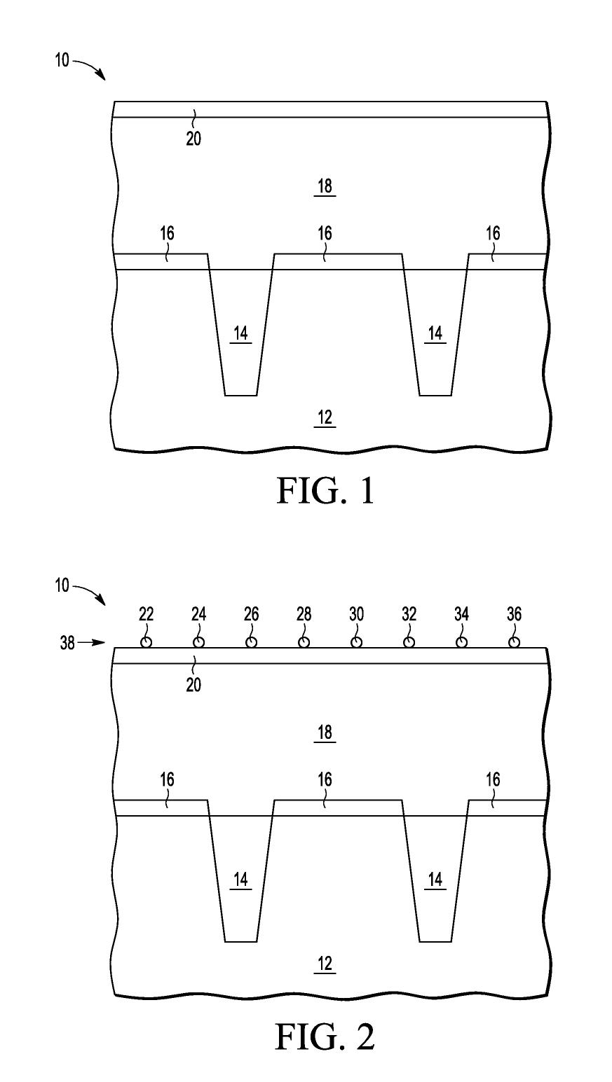

Shown in FIG. 2 is semiconductor device 10 after forming nanocrystals 22, 24, 26, 28, 30, 32, 34, and 36 on dielectric layer 20. Nanocrystals 22, 24, 26, 28, 30, 32, 34, and 36 may be referenced as nanocrystals 38. Nanocrystals are formed to be relatively small, which may be about 50 Angstroms in diameter. They may be formed in a conventional chemical vapor deposition (CVD) process to nucleate and grow the nanocrystals on the dielectric layer. There is typically a further coarsening step so as to obtain larger nanocrystals. Not performing the coarsening step may be a convenient way to achieve relatively smaller nanocrystals. Further the thin layer of polysilicon may be thinner than is typical so that nanocrystals 38 may be further apart than is typical. Nanocrystals 38 may be spaced apart, on average, by 400 Angstroms. With the average diameter at about 50 Angstroms that makes the average pitch, the average center to center distance, at about 450 Angstroms. Note that the range of nanocrystal diameters and the distance between neighboring nanocrystals may vary in a range. For example, the nanocrystal diameters may be 30-120 Angstroms; the distance between neighboring nanocrystals may be 200-500 Angstroms.

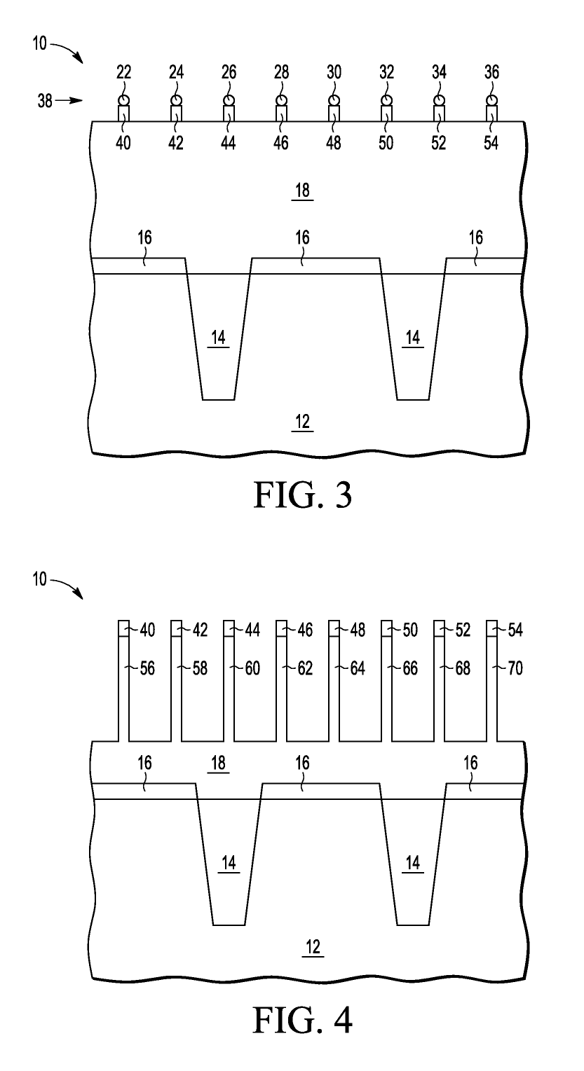

Shown in FIG. 3 is semiconductor device 10 after etching dielectric layer 20 with an anisotropic etch using nanocrystals 38 as a mask to leave hard mask portions 40, 42, 44, 46, 48, 50, 52, and 54 under nanocrystals 22, 24, 26, 28, 30, 32, 34, and 36, respectively. No photoresist is needed because the material of dielectric layer is sufficiently different, oxide is one possibility, from that conductive layer, polysilicon is one possibility, so that dielectric layer 20 can be selectively etched without completely removing nanocrystals 38 before the etch through dielectric layer 20 is complete to form hard mask portions 40, 42, 44, 46, 48, 50, 52, and 54. A material other than a dielectric may be found to be useful in place of dielectric layer 20. It could be conductive because it will be eventually completely removed after performing its function as a hardmask.

Shown in FIG. 4 is a semiconductor device 10 after etching conductive layer 18, selectively, using hard mask portions 40, 42, 44, 46, 48, 50, 52, and 54 as a mask. This leaves pillars 56, 58, 60, 62, 64, 66, 68, and 70 under mask portions 40, 42, 44, 46, 48, 50, 52, and 54, respectively. Each pillar has about the same diameter as the nanocrystal that it is under. The etch into conductive layer 18 is extended partially through it. 56, 58, 60, 62, 64, 66, 68, and 70 may be about as long as two thirds of the thickness of conductive layer 18. Similar to etching dielectric layer 20, conductive layer 18 can be etched selectively to the hard mask portions from dielectric layer 20 without completely removing the hard mask portions before the etch is complete. Since the previously formed nanocrystals above the dielectric hardmask are of the same/similar material (e.g., Si) as the conductive layer 18, those nanocrystals are removed simultaneously during the conductive layer etch. This may also be considered in situ because semiconductor device 10 is not removed during the etch chamber to achieve both the etching of conductive layer 18 an removal of the nanocrystals.

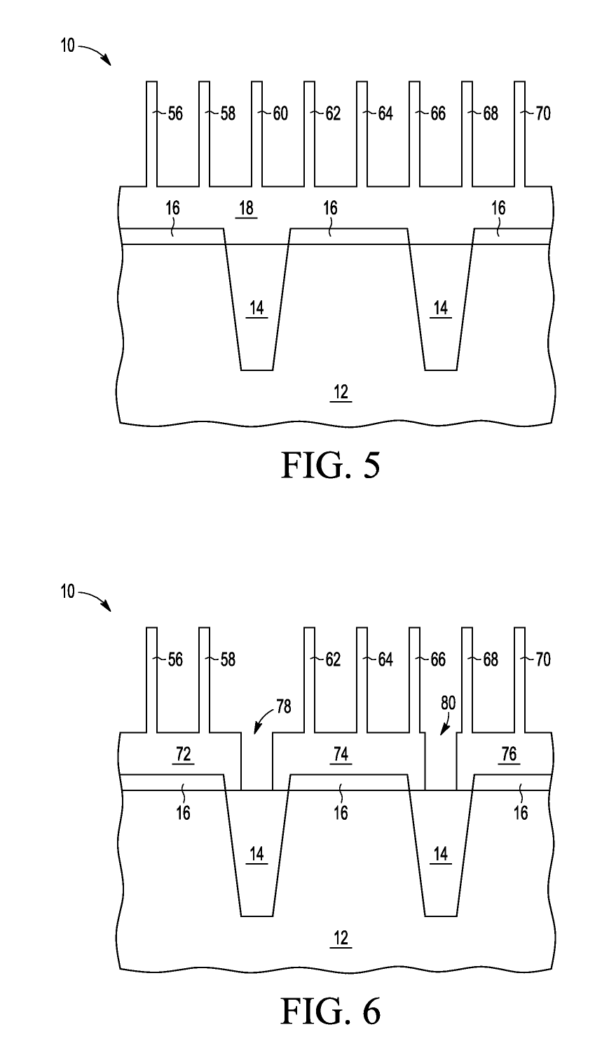

Shown in FIG. 5 is semiconductor device 10 after removing hard mask portions 40, 42, 44, 46, 48, 50, 52, and 54 which may be achieved using a selective wet etch such as HF. This leaves pillars 56, 58, 60, 62, 64, 66, 68, and 70 extending upward from a bottom portion of conductive layer 18 in which the bottom portion may be about one third of the thickness of the conductive layer 18.

Shown in FIG. 6 is semiconductor device 10 after etching through conductive layer 18 of FIG. 5 over isolation 14 to leave floating gates 72, 74, and 76. As a result of this etch, some pillars are also removed. As shown in FIGS. 5 and 6, pillar 60 has been removed by this etch. This etch is useful in separating the floating gates of the memory cells from each other. This separation may not be complete until a subsequent etch that may be aligned to a control gate to be formed.

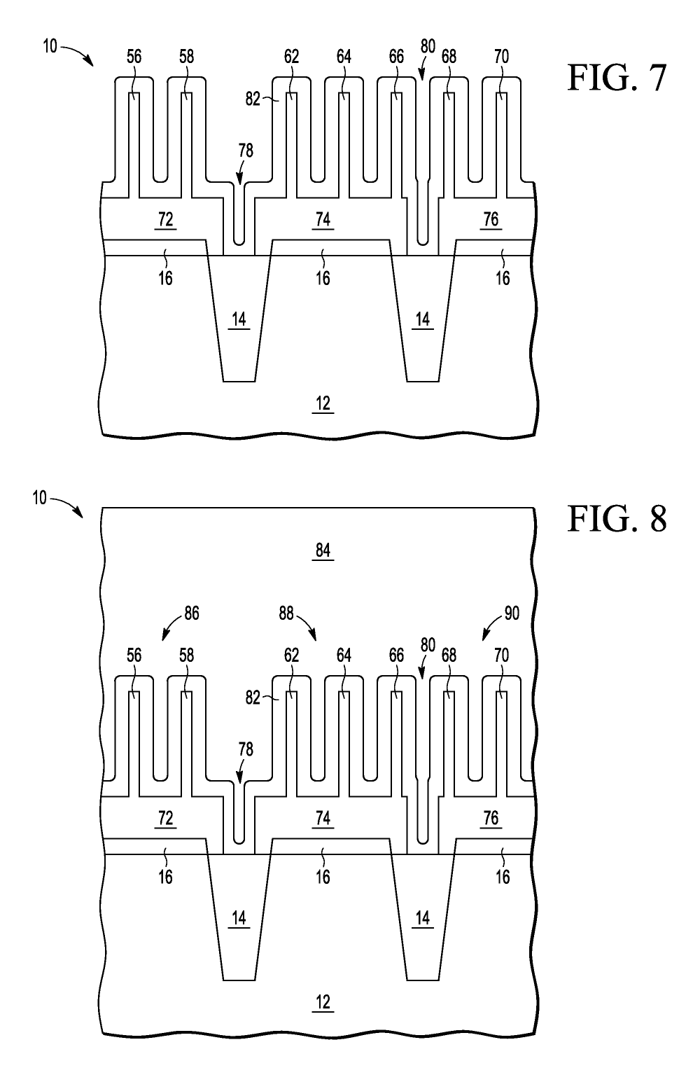

Shown in FIG. 7 is semiconductor device 10 after forming a dielectric layer 82 that may be a combination of oxide, nitride, and oxide (ONO). Dielectric layer 82 may be about 180 Angstroms thick. Dielectric layer 82 must be able to withstand relatively high voltages applied to the control gate to be formed without causing a charge leakage problem. Although it must be thick enough to withstand the relatively high gate voltages, it is not so thick so to completely fill the regions between the pillars. The thickness of dielectric layer 82 is related to the maximum gate voltage that will be applied and the pitch of the nanocrystals is accordingly related to the thickness required for dielectric layer 82 so as to ensure that dielectric layer 82 does not completely fill the gap between the nancrystals. In the case in which the pillars are about two thirds of the height of conductive layer 18 as deposited and shown in FIG. 1, the pillars are about 800 Angstroms high.

Shown in FIG. 8 is semiconductor device 10 after depositing a conductive layer 84, which may be polysilicon, over dielectric layer 82. Conductive layer 84 functions as a control gate for memory cells in which the floating gates of those memory cells are directly under conductive layer 84. As shown in FIG. 8, a memory cell 86 includes conductive layer 84 and floating gate 72, a memory cell 88 includes conductive layer 84 and floating gate 74, and a memory cell 90 includes floating gate 76 and conductive layer 84. Conductive layer 84 functions as the control gate for memory cells 86, 88, and 90 and may be referenced as control gate 84. With control gate 84 extending into gaps between the pillars and thereby adding control gate to floating capacitance, a lower gate voltage is required for program and/or erase. This may result in dielectric layer 82 being thinner which may have the further effect of reducing gate voltage for program and/or erase.

By now it should be appreciated that there has been provided a method for forming a non-volatile memory (NVM) structure. The method includes forming a gate dielectric over a semiconductor substrate. The method further includes forming a floating gate layer over the gate dielectric. The method further includes forming a first dielectric layer over the floating gate layer. The method further includes forming a plurality of nanocrystals over the first dielectric layer. The method further includes etching the first dielectric layer using the plurality of nanocrystals as a mask to form a plurality of dielectric structures of the first dielectric layer, wherein the floating gate layer is exposed between adjacent dielectric structures of the plurality of dielectric structures. The method further includes etching a first depth into the floating gate layer using the plurality of dielectric structures as a mask to form a plurality of patterned structures of the floating gate layer, wherein the first depth is less than a thickness of the floating gate layer. The method further includes removing the plurality of nanocrystals in situ relative to the etching the first depth into the floating gate layer. The method further includes removing the plurality of dielectric structures. The method further includes patterning the floating gate layer to form a floating gate, wherein the floating gate comprises a set of patterned structures of the plurality of patterned structures. The method further includes forming a second dielectric layer over the floating gate, wherein the second dielectric layer is formed over the set of patterned structures and on the floating gate layer between adjacent patterned structures of the set of patterned structures. The method further includes forming a control gate layer over the second dielectric layer, wherein the control gate layer is formed between adjacent patterned structures of the set of patterned structures. The method may have a further characterization by which the step of forming the plurality of nanocrystals over the first dielectric layer is performed such that each nanocrystal of the plurality of nanocrystals has a diameter of less than 100 Angstroms. The method may have a further characterization by which wherein the step of forming the plurality of nanocrystals over the first dielectric layer is performed such that each nanocrystal of the plurality of nanocrystals has an average diameter of about 50 Angstroms. The method may have a further characterization by which the step of forming the plurality of nanocrystals over the first dielectric layer is performed such that a distance between adjacent nanocrystals of the plurality of nanocrystals is about 400 Angstroms. The method may have a further characterization by which the step of etching into the floating gate layer using the plurality of dielectric structures as a mask is performed such that a distance between adjacent patterned structures of the plurality of patterned structures is about 400 Angstroms. The method may have a further characterization by which the step of forming the plurality of nanocrystals is further characterized in that each of the nanocrystals of the plurality of nanocrystals comprises silicon. The method may have a further characterization by which wherein the step of forming a first dielectric layer over the floating gate layer is further characterized in that the first dielectric layer comprises oxide. The method may have a further characterization by which the step of forming the second dielectric layer includes forming a first oxide layer over the floating gate, wherein the first oxide layer is formed over the set of patterned structures and on the floating gate layer between adjacent patterned structures of the set of patterned structures, forming a nitride layer on the first oxide layer, and forming a second oxide layer on the nitride layer. The method may have a further characterization by which the step of forming the floating gate layer is further characterized in that the floating gate layer comprises polysilicon. The method may have a further characterization by which the step of forming the control gate layer is further characterized in that the control gate layer comprises a material selected from a group consisting of polysilicon and metal. The method may have a further characterization by which prior to the step of patterning the floating gate layer, the method further comprises performing an anneal in an ambient containing hydrogen. The method may have a further characterization by which the step of etching the first depth into the floating gate layer is further characterized in that the first depth is at least half of the thickness of the floating gate layer.

Also described is a method method for forming a non-volatile memory (NVM) structure. The method includes forming a gate dielectric over a semiconductor substrate. The method further includes forming a floating gate layer over the gate dielectric. The method further includes forming a first dielectric layer over the floating gate layer. The method further includes forming a plurality of nanocrystals over the first dielectric layer, wherein each nanocrystals of the plurality of nanocrystals has diameter of about 50 Angstroms and a distance between adjacent nanocrystals of the plurality of nanocrystals is at least 300 Angstroms. The method further includes etching the first dielectric layer using the plurality of nanocrystals as a mask to form a plurality of dielectric structures of the first dielectric layer, wherein the floating gate layer is exposed between adjacent dielectric structures of the plurality of dielectric structures. The method further includes etching a first depth into the floating gate layer using the plurality of dielectric structures as a mask to form a plurality of patterned structures of the floating gate layer, wherein the first depth is less than a thickness of the floating gate layer. The method further includes removing the plurality of nanocrystals in situ with the etching the first depth of the plurality of dielectric structures. The method further includes removing the plurality of dielectric structures. The method further includes patterning the floating gate layer to form a floating gate, wherein the floating gate comprises a set of patterned structures of the plurality of patterned structures. The method further includes forming a second dielectric layer over the floating gate, wherein the second dielectric layer is formed over the set of patterned structures and on the floating gate layer between adjacent patterned structures of the set of patterned structures. The method further includes forming a control gate layer over the second dielectric layer, wherein the control gate layer is formed between adjacent patterned structures of the set of patterned structures. The method may have a further characterization by which the step of forming the plurality of nanocrystals over the first dielectric layer is performed such that a distance between adjacent nanocrystals of the plurality of nanocrystals is about 400 Angstroms. The method may have a further characterization by which the step of forming the plurality of nanocrystals over the first dielectric layer is performed such that each nanocrystal of the plurality of nanocrystals has a diameter of at most 50 Angstroms. The method may have a further characterization by which wherein the step of forming the plurality of nanocrystals is further characterized in that each of the nanocrystals of the plurality of nanocrystals comprises silicon. The method may have a further characterization by which wherein the step of forming a first dielectric layer over the floating gate layer is further characterized in that the first dielectric layer comprises oxide. The method may have a further characterization by which wherein the step of forming the second dielectric layer includes forming a first oxide layer over the floating gate, wherein the first oxide layer is formed over the set of patterned structures and on the floating gate layer between adjacent patterned structures of the set of patterned structures, forming a nitride layer on the first oxide layer, and forming a second oxide layer on the nitride layer. The method may have a further characterization by which the step of forming the floating gate layer is further characterized in that the floating gate layer comprises polysilicon, and the step of forming the control gate layer is further characterized in that the control gate layer comprises polysilicon.

Described also is a method for forming a non-volatile memory (NVM) structure. The method includes forming a gate dielectric over a semiconductor substrate. The method further includes forming a floating gate layer over the gate dielectric. The method further includes forming an oxide layer over the floating gate layer. The method further includes forming a plurality of silicon nanocrystals over the oxide layer, wherein each silicon nanocrystals of the plurality of silicon nanocrystals has a diameter of about 50 Angstroms and a distance between adjacent silicon nanocrystals of the plurality of silicon nanocrystals is at least 300 Angstroms. The method further includes etching the oxide layer using the plurality of silicon nanocrystals as a mask to form a plurality of oxide structures of the oxide layer, wherein the floating gate layer is exposed between adjacent oxide structures of the plurality of oxide structures. The method further includes etching a first depth into the floating gate layer using the plurality of oxide structures as a mask to form a plurality of patterned structures of the floating gate layer, wherein the first depth is at least half of a thickness of the floating gate layer and less than an entire thickness of the floating gate layer. The method further includes removing the plurality of silicon nanocrystals in situ relative to the etching the first depth into the floating gate layer. The method further includes removing the plurality of oxide structures. The method further includes patterning the floating gate layer to form a floating gate, wherein the floating gate comprises a set of patterned structures of the plurality of patterned structures. The method further includes forming an oxide-nitride-oxide layer over the floating gate, wherein the oxide-nitride-oxide layer is formed over the set of patterned structures and on the floating gate layer between adjacent patterned structures of the set of patterned structures. The method further includes forming a control gate layer over the oxide-nitride-oxide layer, wherein the control gate layer is formed between adjacent patterned structures of the set of patterned structures.

Although the invention is described herein with reference to specific embodiments, various modifications and changes can be made without departing from the scope of the present invention as set forth in the claims below. For example, specific materials and thicknesses were described, but other materials and thicknesses may be used. Dimensions tend to shrink and materials may change. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A method for forming a non-volatile memory (NVM) structure, the method comprising:
forming a gate dielectric over a semiconductor substrate;
forming a floating gate layer over the gate dielectric;
forming a first dielectric layer over the floating gate layer;
forming a plurality of nanocrystals over the first dielectric layer;
etching the first dielectric layer using the plurality of nanocrystals as a mask to form a plurality of dielectric structures of the first dielectric layer, wherein the floating gate layer is exposed between adjacent dielectric structures of the plurality of dielectric structures;
etching a first depth into the floating gate layer using the plurality of dielectric structures as a mask to form a plurality of patterned structures of the floating gate layer, wherein the first depth is less than a thickness of the floating gate layer;
removing the plurality of nanocrystals in situ relative to the etching the first depth into the floating gate layer;
removing the plurality of dielectric structures;
patterning the floating gate layer to form a floating gate, wherein the floating gate comprises a set of patterned structures of the plurality of patterned structures;
forming a second dielectric layer over the floating gate, wherein the second dielectric layer is formed over the set of patterned structures and on the floating gate layer between adjacent patterned structures of the set of patterned structures; and
forming a control gate layer over the second dielectric layer, wherein the control gate layer is formed between adjacent patterned structures of the set of patterned structures.

2. The method of claim 1, wherein the step of forming the plurality of nanocrystals over the first dielectric layer is performed such that each nanocrystal of the plurality of nanocrystals has a diameter of less than 100 Angstroms.

3. The method of claim 1, wherein the step of forming the plurality of nanocrystals over the first dielectric layer is performed such that each nanocrystal of the plurality of nanocrystals has an average diameter of about 50 Angstroms.

4. The method of claim 1, wherein the step of forming the plurality of nanocrystals over the first dielectric layer is performed such that a distance between adjacent nanocrystals of the plurality of nanocrystals is about 400 Angstroms.

5. The method of claim 1, wherein the step of etching into the floating gate layer using the plurality of dielectric structures as a mask is performed such that a distance between adjacent patterned structures of the plurality of patterned structures is about 400 Angstroms.

6. The method of claim 1, wherein the step of forming the plurality of nanocrystals is further characterized in that each of the nanocrystals of the plurality of nanocrystals comprises silicon.

7. The method of claim 1, wherein the step of forming a first dielectric layer over the floating gate layer is further characterized in that the first dielectric layer comprises oxide.

8. The method of claim 1, wherein the step of forming the second dielectric layer comprises:
forming a first oxide layer over the floating gate, wherein the first oxide layer is formed over the set of patterned structures and on the floating gate layer between adjacent patterned structures of the set of patterned structures;
forming a nitride layer on the first oxide layer; and
forming a second oxide layer on the nitride layer.

9. The method of claim 1, wherein the step of forming the floating gate layer is further characterized in that the floating gate layer comprises polysilicon.

10. The method of claim 1, wherein the step of forming the control gate layer is further characterized in that the control gate layer comprises a material selected from a group consisting of polysilicon and metal.

11. The method of claim 1, wherein prior to the step of patterning the floating gate layer, the method further comprises performing an anneal in an ambient containing hydrogen.

12. The method of claim 1, wherein the step of etching the first depth into the floating gate layer is further characterized in that the first depth is at least half of the thickness of the floating gate layer.

13. A method for forming a non-volatile memory (NVM) structure, the method comprising:
forming a gate dielectric over a semiconductor substrate;
forming a floating gate layer over the gate dielectric;
forming a first dielectric layer over the floating gate layer;
forming a plurality of nanocrystals over the first dielectric layer, wherein each nanocrystals of the plurality of nanocrystals has diameter of about 50 Angstroms and a distance between adjacent nanocrystals of the plurality of nanocrystals is at least 300 Angstroms;
etching the first dielectric layer using the plurality of nanocrystals as a mask to form a plurality of dielectric structures of the first dielectric layer, wherein the floating gate layer is exposed between adjacent dielectric structures of the plurality of dielectric structures;
etching a first depth into the floating gate layer using the plurality of dielectric structures as a mask to form a plurality of patterned structures of the floating gate layer, wherein the first depth is less than a thickness of the floating gate layer;
removing the plurality of nanocrystals in situ with the etching the first depth of the plurality of dielectric structures;
removing the plurality of dielectric structures;
patterning the floating gate layer to form a floating gate, wherein the floating gate comprises a set of patterned structures of the plurality of patterned structures;
forming a second dielectric layer over the floating gate, wherein the second dielectric layer is formed over the set of patterned structures and on the floating gate layer between adjacent patterned structures of the set of patterned structures; and
forming a control gate layer over the second dielectric layer, wherein the control gate layer is formed between adjacent patterned structures of the set of patterned structures.

14. The method of claim 13, wherein the step of forming the plurality of nanocrystals over the first dielectric layer is performed such that a distance between adjacent nanocrystals of the plurality of nanocrystals is about 400 Angstroms.

15. The method of claim 14, wherein the step of forming the plurality of nanocrystals over the first dielectric layer is performed such that each nanocrystal of the plurality of nanocrystals has a diameter of at most 50 Angstroms.

16. The method of claim 13, wherein the step of forming the plurality of nanocrystals is further characterized in that each of the nanocrystals of the plurality of nanocrystals comprises silicon.

17. The method of claim 13, wherein the step of forming a first dielectric layer over the floating gate layer is further characterized in that the first dielectric layer comprises oxide.

18. The method of claim 13, wherein the step of forming the second dielectric layer comprises:
forming a first oxide layer over the floating gate, wherein the first oxide layer is formed over the set of patterned structures and on the floating gate layer between adjacent patterned structures of the set of patterned structures;
forming a nitride layer on the first oxide layer; and
forming a second oxide layer on the nitride layer.

19. The method of claim 13, wherein the step of forming the floating gate layer is further characterized in that the floating gate layer comprises polysilicon, and the step of forming the control gate layer is further characterized in that the control gate layer comprises polysilicon.

20. A method for forming a non-volatile memory (NVM) structure, the method comprising:
forming a gate dielectric over a semiconductor substrate;
forming a floating gate layer over the gate dielectric;
forming an oxide layer over the floating gate layer;
forming a plurality of silicon nanocrystals over the oxide layer, wherein each silicon nanocrystals of the plurality of silicon nanocrystals has a diameter of about 50 Angstroms and a distance between adjacent silicon nanocrystals of the plurality of silicon nanocrystals is at least 300 Angstroms;
etching the oxide layer using the plurality of silicon nanocrystals as a mask to form a plurality of oxide structures of the oxide layer, wherein the floating gate layer is exposed between adjacent oxide structures of the plurality of oxide structures;
etching a first depth into the floating gate layer using the plurality of oxide structures as a mask to form a plurality of patterned structures of the floating gate layer, wherein the first depth is at least half of a thickness of the floating gate layer and less than an entire thickness of the floating gate layer;
removing the plurality of silicon nanocrystals in situ relative to the etching the first depth into the floating gate layer;
removing the plurality of oxide structures;
patterning the floating gate layer to form a floating gate, wherein the floating gate comprises a set of patterned structures of the plurality of patterned structures;
forming an oxide-nitride-oxide layer over the floating gate, wherein the oxide-nitride-oxide layer is formed over the set of patterned structures and on the floating gate layer between adjacent patterned structures of the set of patterned structures; and
forming a control gate layer over the oxide-nitride-oxide layer, wherein the control gate layer is formed between adjacent patterned structures of the set of patterned structures.
